(19) United States
(12) Patent Application Publication
(10) Pub. No.: US 2018/0269371 A1
(43) Pub. Date: Sep. 20, 2018

(54) Cooling Arrangement For An Electronic Component

(71) Applicant: Siemens Aktiengesellschaft, München (DE)

(72) Inventors: Martin Franke, Berlin (DE); Peter Frühauf, Falkensee (DE); Rüdiger Knofe, Teltow (DE); Bernd Müller, Falkenberg (DE); Stefan Nerreter, Heidesee OT Blossin (DE); Michael Niedermayer, Glienicke (DE); Ulrich Wittreich, Velten (DE); Manfred Zäske, Berlin (DE)

(73) Assignee: Siemens Aktiengesellschaft, Muenchen (DE)

(21) Appl. No.: 15/761,485

(22) PCT Filed: Sep. 7, 2016
(86) PCT No.: PCT/EP2016/071036

§ 371 Date: Mar. 20, 2018

(30) Foreign Application Priority Data
Sep. 21, 2015 (DE) 10 2015 218 083.2

(51) Int. Cl. H01L 35/30; H02H 5/04; H05K 1/02; F04D 33/00; F04D 25/06

(52) U.S. Cl. CPC H01L 35/30; H02H 5/04; H05K 1/0203; F04D 33/00; H05K 2201/10151; H05K 2201/064; H05K 2201/066; H05K 2201/10037; H05K 2201/10219; F04D 25/06

(57) ABSTRACT

The present disclosure relates to a cooling arrangement for an electronic component. Some embodiments of the teachings thereof may include a heat sink with a contact surface as an interface for the electronic component. For example, a cooling arrangement for an electronic component may include: a heat sink with a contact surface for the electronic component; a converter for the conversion of thermal energy into useful energy; a functional element driven by the useful energy; and an active cooling device for the heat sink or for the electronic component.

### CROSS-REFERENCE TO RELATED APPLICATIONS

This application is a U.S. National Stage Application of International Application No. PCT/EP2016/071036 filed Sep. 7, 2016, which designates the United States of America, and claims priority to DE Application No. 10 2015 218 083.2 filed Sep. 21, 2015, the contents of which are hereby incorporated by reference in their entirety.

### TECHNICAL FIELD

The present disclosure relates to a cooling arrangement for an electronic component. Some embodiments of the teachings thereof may include a heat sink with a contact surface as an interface for the electronic component.

### BACKGROUND

Electronic components may be equipped with passive cooling elements which permit the evacuation of heat losses generated during the operation of said electronic components. The progressive increase in the through-ratings of electronic components, coupled with the simultaneous miniaturization of the components employed, is such that increasingly large quantities of heat must be transported through each available unit of surface area of an electronic component. It is the increasingly small contact surfaces between electronic components, as the heat source, and the heat sinks or coolants employed which handicap the effective evacuation of heat from electronic components. However, the reliable evacuation of heat is a precondition for the reliable operation of the circuits made up of electronic components.

In conventional heat sink technologies, heat sinks, for example of aluminum construction, are employed having a mounting side, by means of which they can be fitted to a boundary surface of the electronic component. In many cases, heat sinks employed incorporate ribs for the enlargement of the surface area available for the dissipation of heat, and can be cost-effectively produced, for example from aluminum, in the form of extruded profiles. However, the potential dissipation of heat from such passive heat sinks is subject to physical limitations, such that conventional cooling elements are reaching their performance limits for heat evacuation. In place of aluminum, a more effective thermally-conductive metal, such as copper, may be used. However, heat sinks of this type, on the grounds of higher material and manufacturing costs, are not cost-effective.

Another typical option includes active cooling by forced convection of a coolant, for example air, which is moved by means of a ventilator, or a liquid which is employed, for example, in “heat pipes”. Heat evacuation solutions of this type are more expensive than passive cooling and, moreover, are dependent upon an energy source.

### SUMMARY

The teachings of the present disclosure may be embodied in a cooling arrangement for an electronic component or an electronic assembly, in which a cooling arrangement of this type is employed, by means of which reliable cooling is possible with a relatively high cooling capacity, and using cost-effective technical means.

For example, some embodiments may include a cooling arrangement for an electronic component (11), having a heat sink (13) with a contact surface (12) for the electronic component (11), characterized in that the cooling arrangement comprises: a converter (14) for the conversion of thermal energy into useful energy, and as a functional element, in which this useful energy can be stored, a cooling device (21) for the heat sink or for the electronic component (11).

In some embodiments, the converter (14) is constituted by a thermoelectric generator.

In some embodiments, the thermoelectric generator and the functional element are connected to an electrical energy store (20).

In some embodiments, the cooling device is constituted by a piezo fan, a motor-driven fan or a Peltier element.

In some embodiments, a functional element is constituted by a monitoring device (24) and/or an indicator device and/or a data transmission device.

In some embodiments, the converter (14) is bonded with a supplementary heat sink (15).

In some embodiments, a plurality of modules in the cooling arrangement constitute a structural unit.

In some embodiments, the converter (14) is bonded with the heat sink (13).

In some embodiments, the heat sink (13) incorporate ribs (30), and the converter (14) is arranged between adjoining ribs (30).

In some embodiments, a control module (18) is provided for the functional elements (21, 24, 26, 27) and/or for the thermoelectric generator, which employs the energy generated by the thermoelectric generator.

As another example, some embodiments may include an electronic assembly having an electronic component and a cooling arrangement as described above, characterized in that the cooling arrangement is comprised of a plurality of modules which, in combination with the electronic component 11, are mounted on a circuit carrier (29).

In some embodiments, the converter (14) is arranged on a reverse side of the circuit carrier.

In some embodiments, the converter (14) is bonded to the electronic component (11), or to a thermal conduction path (31) originating from the electronic component (11).

### BRIEF DESCRIPTION OF THE DRAWINGS

Further details of the present disclosure are described hereinafter, with reference to the drawings. Identical or corresponding elements in the drawing are identified by the same reference symbols and, accordingly, are only described repeatedly to the extent required by differences between the individual figures. In the figures:

FIG. 1 is a block circuit diagram which shows an exemplary embodiment of a cooling arrangement according to the teachings of the present disclosure;

FIG. 2 is a diagram showing the thermal flux of different quantities of heat Q in the embodiment according to FIG. 1; and

FIGS. 3-7 show various exemplary embodiments of the electronic assembly or of the cooling arrangement according to the teachings of the present disclosure, partially in section.

### DETAILED DESCRIPTION

In some embodiments, the cooling arrangement incorporates a converter for the conversion of thermal energy into useful energy. Thermal energy is supplied by the electronic component to be cooled, to which the heat sink is connected in a thermally conductive manner. The useful energy generated by the converter can be, for example, electrical or mechanical energy and may be stored in a functional element, which is configured as a part of the cooling arrangement.

In some embodiments, cooling devices are employed as functional elements for the heat sink. As a cooling device, for example, a “piezo fan” can be employed, wherein the fan is driven by a piezo element and, in this manner, is responsible for the movement of air. A motor-driven fan can also be employed as an alternative. Finally, a further Peltier element can be employed, which is supplied with electrical energy and is thus employed as a heat pump. The cooling device can be employed for the cooling of the heat sink, or for the direct cooling of the electronic component to be cooled.

Including a converter may improve the evacuation of heat from the electronic component, such that the converter supports the heat sink in the cooling of the electronic component, thereby enhancing the cooling capacity. The associated additional expenditure may permit the exploitation of the useful energy thus generated, which can be employed in a further functionality of the electronic assembly of which the electronic component forms a part of. Thus, cost savings associated with the saving of an energy source or the employment of an energy source with a reduced power take-up are available, thereby offsetting the additional expenditure associated with the cooling arrangement.

In some embodiments, the converter can comprise a device of bimetallic construction or formed of a shape memory alloy, such as nickel-titanium. The converter involved converts thermal energy into useful mechanical energy. This useful mechanical energy can be employed, for example, for the propulsion of a cooling device such as a fan.

In some embodiments, the converter can also be configured as a thermoelectric generator. A generator of this type generates useful energy in the form of electrical energy. A thermoelectric generator of this type can be embodied, for example, as a Peltier element. In some embodiments, electrical energy can be employed by a variety of functional elements.

If the functional element requires a different type of useful energy to that supplied by the converter, the functional element may be equipped with a further converter, which converts the useful energy delivered by the converter into the useful energy required by the functional element. If, for example, a thermoelectric generator is employed as a converter, the motor of a ventilator or the piezo actuator of a piezo fan constitutes the further converter in the functional element, for the conversion of electrical energy into mechanical energy. Useful electrical energy has an advantage, in that a variety of cost-effective and reliably-operating converters are available, which can be employed as further converters.

Useful electrical energy has a further advantage, in that the thermoelectric generator and the functional element can respectively be connected to an energy store for electrical energy. Consequently, stored electrical energy can be employed for the operation of the functional element, if no thermal energy supply is available from the electronic component. It is thus possible to maintain the supply of electrical energy to functionalities, the operation of which is required independently of the operation of the electronic component. It should be noted that, even in the absence of the employment of an electrical energy store, it is possible that, further to the termination of the operation of the electronic component, electricity be generated while the electronic component cools. Consequently, for example, cooling by means of a cooling device can be supported without the use of external energy sources, or another functionality can remain in service.

In some embodiments, other functionalities can be delivered, wherein the functional element is constituted by a monitoring device and/or an indicator device and/or a data transmission device. Relevant indicator devices include, for example, LEDs which indicate, for example, the overheating of the electronic component. As monitoring devices, for example, sensors can be employed which automatically disconnect the component in the event of overheating.

Moreover, functional elements can also be operated which are not directly involved in the cooling process of the cooling arrangement. For example, data from the electronic assembly can be relayed to an external device via a data transmission device. This external device can be, for example, a superordinate control installation, which executes the common control of a combination of electronic assemblies, as is the case, for example, in industrial production plants. The data transmission device can be executed, for example, in the form of a mechanical interface (plug-in connection) or a wireless interface (radio link, infrared link or similar). The energy supply to the functionalities indicated can be delivered by means of the above-mentioned storage of electrical energy, independently of the operation of the electronic component.

In some embodiments, the converter is bonded to a supplementary heat sink. The supplementary heat sink may conduct heat away from the converter, as a result of which a larger temperature drop is generated in the converter between the electronic component and the supplementary heat sink. This permits generation (conversion) of a larger quantity of useful energy, which is available for delivery to the functional component. The supplementary heat sink can be operated in a different temperature range to that of the heat sink which is provided for the electronic component.

In some embodiments, the cooling arrangement constitutes an assembly. This means that all the elements which, in combination, constitute the cooling arrangement are combined in a structural unit. The relevant elements are the heat sink, the converter, the functional element, the further converter, and the supplementary heat sink. Of course, it is not necessary for all the elements to be incorporated in the assembly.

The combination of at least a part of these elements in an assembly may provide an advantage, in that the installation of the latter can be simplified, thereby reducing assembly costs associated with final assembly, and permitting the production of larger component runs, with corresponding cost benefits (economies of scale), for multiple products. The fitting of the cooling arrangement according to the invention is thus more cost-effective. Specifically, the bonding of the converter with the heat sink may provide a means of supporting the cooling capacity of the heat sink.

In some embodiments, the heat sink can incorporate ribs, and the converter can be arranged between adjoining ribs. In some embodiments, the converter is also bonded with the ribs. The arrangement of the converter between the ribs provides that, in this location, the converter is protected against damage, and no additional structural space outside the heat sink is required. It is moreover possible for the converter between the ribs to be equipped with a cooling device. In some embodiments, the cooling device is then also arranged in a protected position between the ribs. This is particularly useful where sensitive mechanical components, such as fans, are employed. Moreover, the cooling effect can be initiated directly between the ribs, thus permitting the more effective exploitation of the effects of surface enlargement associated with the ribs.

For the functional element and/or the thermoelectric generator, a control module can be additionally employed, which distributes the energy generated by the thermoelectric generator. Accordingly, the control module likewise constitutes a functional element. By means of the control module, service-related operational sequences of the cooling arrangement can be controlled, such that the latter can be operated, in a service-related manner, in various modes. The above-mentioned sensors, which constitute further functional elements, can also be employed for this purpose.

In some embodiments, the above-described electronic assembly, wherein the cooling arrangement comprises a plurality of modules, and the electronic component are mounted on a circuit carrier. For the electrical connection of the various modules, printed conductors can be provided, which are arranged on the circuit carrier. In some embodiments, the modules may be integrated in the electronic assembly. In some embodiments, the converter, as a single module, can specifically be arranged in an optimum location, at which the conversion of thermal energy into useful energy can be executed most efficiently. In some embodiments, the converter can be arranged on a reverse side of the circuit carrier, the side which is averted from the side upon which the electronic components to be cooled are mounted. In this case, through-contacts can be arranged in the circuit carrier, the thermal conductivity of which permits the transmission of energy generated by the electronic components to the converter.

As an electric circuit carrier, for example, a printed circuit board can be employed. However, other structural forms of the circuit carrier are also conceivable. For example, the electronic assembly can be arranged in a housing, wherein the latter, for example, can be produced in the form of a “molded interconnect device” (MID). The employment of film-type circuit carriers is also conceivable.

In some embodiments, the converter is directly bonded to the electronic components of the electronic assembly, or to a thermal conduction path originating from the electronic components. The thermal conduction path, as described above, can be constituted by through-contacts, to permit the evacuation of heat to the reverse side of the circuit carrier. In some embodiments, the thermal conduction path is disposed on that side of the circuit carrier upon which the electronic component to be cooled is also arranged (the front side). This permits the fitting of the converter in the environment of the electronic component. The employment of thermal conduction paths provides an advantage in that, with respect to the arrangement of the components of the cooling arrangement, a greater degree of freedom in structural design is provided.

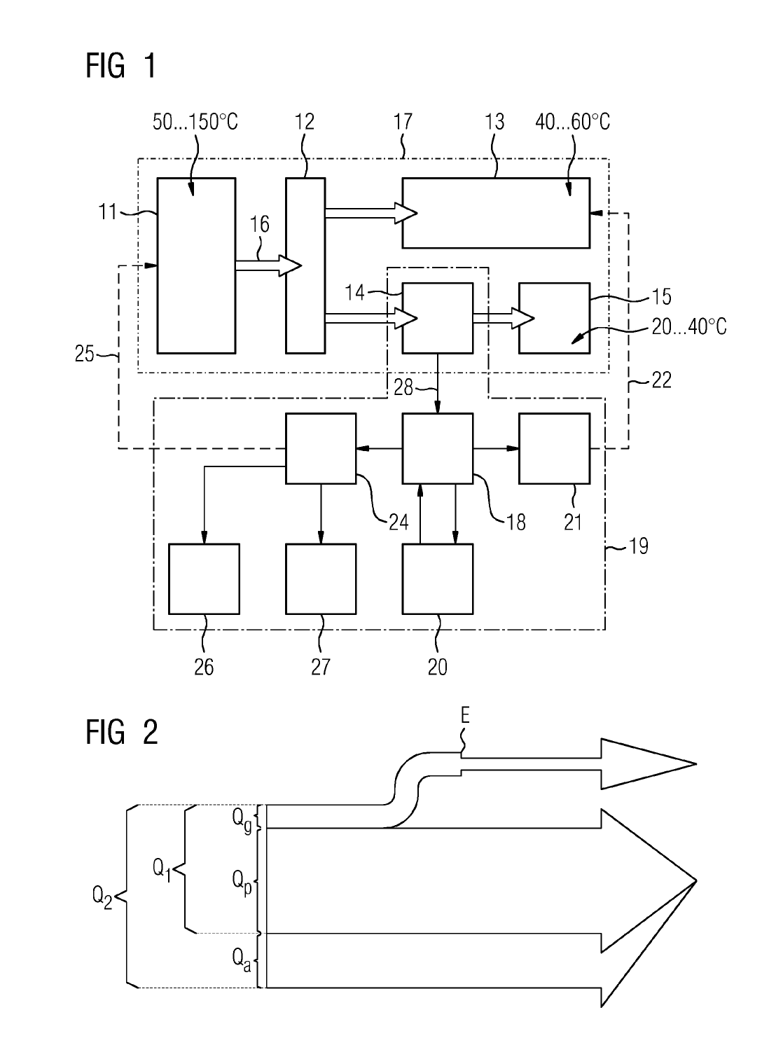

In FIG. 1, the individual elements of the electronic assembly are represented in a block circuit diagram. An electronic component assumes a temperature between 50 and 150° C. This heat is evacuated to a heat sink 13 via a thermal interface 12.

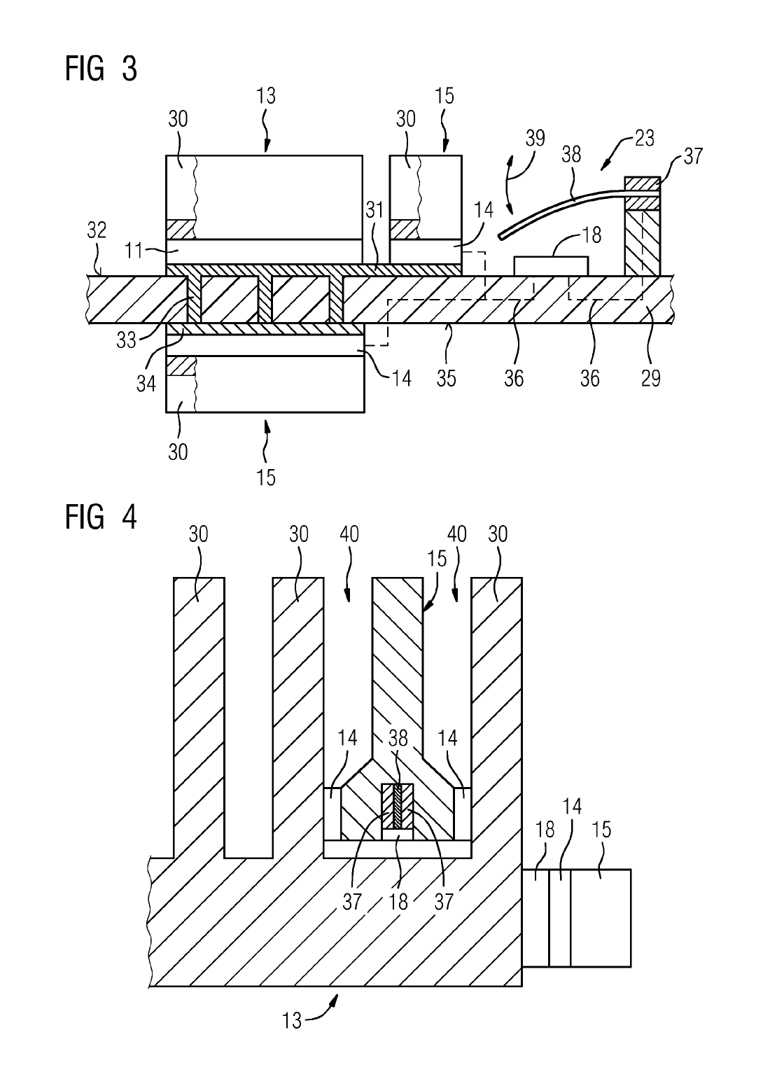

Additionally to the heat sink 13, via which the major proportion of heat Qₚ is transmitted, a converter 14 is exposed to a quantity of heat Q_{g} (cf. FIG. 2). Via this converter, surplus heat is dissipated to a supplementary heat sink 15. However, this supplementary heat sink 15 is operated in a different temperature range to that of the heat sink 13. From FIG. 1, it will be seen that the heat sink 13 in the present exemplary embodiment, at its coolest point, achieves a temperature between 40 and 60° C., whereas the supplementary heat sink 15, at its coolest point, assumes a temperature between 20 and 40° C. In FIG. 1, the thermal flux between the above-mentioned components is represented by broad arrows 16, wherein the breadth thereof gives no indication of the quantity of heat flowing.

The above-mentioned elements 11, 12, 13, 14, 15 may be described as a thermal system 17, the system limits of which are indicated by a dash-dotted line. The converter 14 comprises a thermoelectric generator (for example as a Peltier element) and generates electrical energy by means of the temperature difference between the interface 12 and the supplementary heat sink 15. This energy is delivered to a control module 18, wherein the control module 18 assumes the energy management of a cooling arrangement 19, the system limits of which are likewise indicated by a dash-dotted line. The converter 14 is associated with this cooling arrangement 19 and simultaneously constitutes an element of the thermal system 17 and is thus to be understood as the linking element between the two systems.

Depending upon the operating state of the cooling arrangement 19, the control module 18 permits the following operating states. If the electrical energy generated by the converter 14 is not required, or is only partially required, an energy store 20 in the form of a chargeable battery is supplied by means of the control module. Conversely, stored electrical energy from the energy store 20 can be delivered to the control module 18, if the converter 14 is not generating sufficient electrical energy.

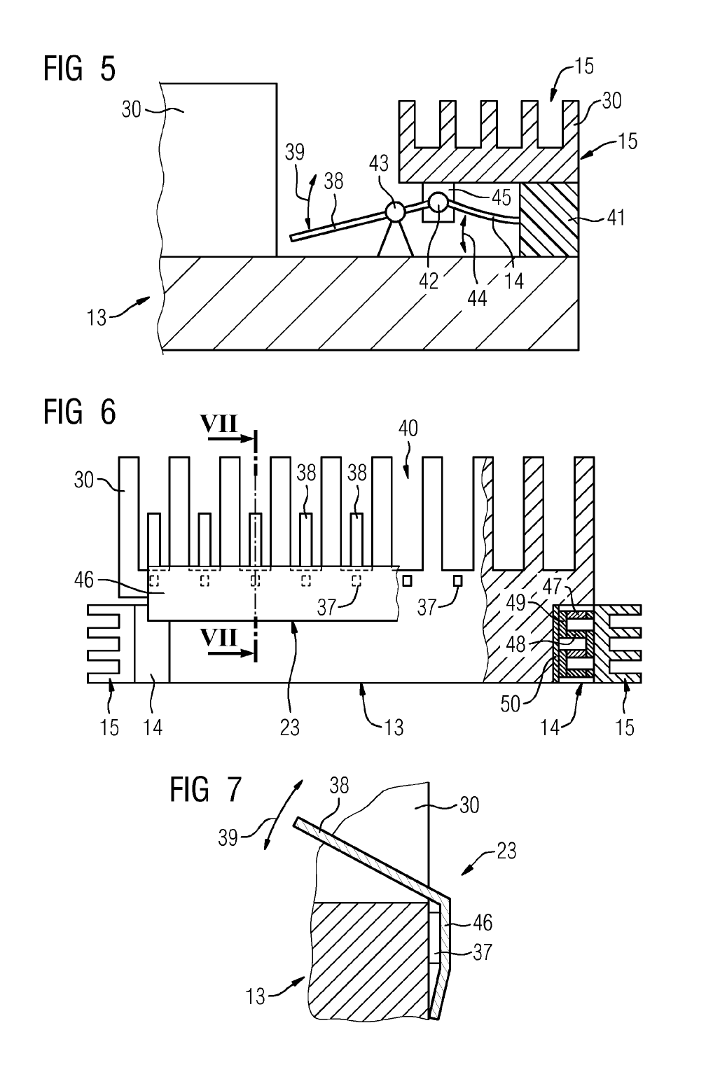

Electrical energy can be employed for various functional elements 21, 22, 23. These functional elements can be actuated by the control module 18 or can execute their function independently. In the latter case, only the energy supply is controlled by the control module 18. One example of a functional element is a cooling device 21. This cooling device 21 is employed to achieve an additional cooling effect for the electrical component 11. To this end, the cooling device 21 acts on the heat sink 13 in the direction indicated by the dashed arrow 22, which can thus deliver a higher cooling capacity to the electrical component 11 (c.f. the description associated with FIG. 2). The cooling device 21 can be, for example, a piezo fan 23 according to FIG. 3.

In some embodiments, the functional element comprises a monitoring device 24 for the electronic component 11. By this arrangement, for example, protection against overheating can be realized, wherein the monitoring device 24, in accordance with the dashed arrow 25, switches off the electronic component 11 to protect against overheating. In such an operating state, the converter 14 delivers the requisite current for this purpose, such that the operation of the monitoring device 24 is maintained. The monitoring device 24 can also generate an indication of an overload on an indicator device 26, e.g. a LED. Moreover, a data transmission device 27 can also be provided, such that a monitoring result (and thus e.g. the current temperature of the electronic component 11) can be relayed to an unrepresented computer, in either a wired or a wireless arrangement, for the purposes of external data process. In this manner, a monitoring and control function which encompasses a plurality of (unrepresented) electronic components can be realized, wherein the data required for this purpose can be determined and transmitted using an independent power supply, as waste heat from the electrical component 11 permits the generation of energy. As a result, the reliability of the monitoring system is advantageously enhanced wherein, simultaneously, the cooling capacity for the electronic component 11 is increased.

The flux of electrical energy between the elements 14, 18, 20, 21, 24, 26 and 27 is indicated by the narrow arrow 28. This only indicates the electrical energy flux for the supply of energy to these elements. Signal flows between the individual elements are not represented in FIG. 1. As can clearly be seen from FIG. 1, the supply of energy to the elements (for example 26, 27) does not necessarily proceed directly via the control module 18. The monitoring device 24 supplies the indicator device 26 and the data transmission device 27 with electric current, which they themselves draw from the control module 18.

FIG. 2 shows a schematic representation of the thermal flux associated with the heat generated in the electrical component 11. The greater this thermal flux, the greater the cooling effect achieved by means of the cooling measures for the electronic component 11. Firstly, the quantity of heat Qₚ is evacuated from the electronic component 11 by means of passive cooling via the heat sink 13 (thermal conduction). The converter 14, which is configured as a thermoelectric generator, likewise evacuates a second quantity of heat Q_{g} by thermal conduction. This quantity of heat Q_{g} thus increases the cooling effect applied to the electrical component 11 such that, according to the invention, the quantity of heat Q₁ is evacuated the converter 14 then generates the quantity of electricity E, as a result of which the thermal flux Q_{g} is reduced.

If, as proposed in FIG. 1, an additional active cooling device 21 is operated, the associated active cooling increases the cooling effect of the heat sink 13. Consequently, in addition, as a result of active cooling, the quantity of heat Qₐ is evacuated from the electric component 11 whereby, according to the invention, the total quantity of heat evacuated is increased to Q₂. The heat sink 13 itself requires no modification, such that there is no resulting increased space requirement for the electrical component 11.

FIG. 3 represents an exemplary embodiment of the cooling arrangement. The electrical component 11 is mounted on a circuit carrier 29 in the form of a printed circuit board. The heat sink 13 is arranged on the upper side of the electrical component 11. As the heat sink is shown in a partial cutaway representation, it can be seen that the latter incorporates ribs 30. On its mounting side, the electrical component 11 is mounted on a thermal conduction path 31, which is applied in the form of a metal layer on the front side 32 of the circuit carrier 29. The thermal conduction path 31 is completed by thermal through-contacts 33, which bond with a metal layer 34 on the reverse side 35 of the circuit carrier 29. On the layer 34 and on the thermal conduction path 31 respectively, a converter 14 in the form of a Peltier element is arranged, the respective opposing side of which is respectively fitted with a supplementary heat sink 15. This supplementary heat sink 15 likewise incorporates ribs 30. The dashed lines 36 represent conductors which connect the two converters 14 to the control module 18. This additionally controls a second converter, configured as a piezo actuator 37, which constitutes an element of the cooling apparatus 23. The piezo actuator 37 drives a fan 38, which oscillates along the double-headed arrow 39, thereby moving air along the ribs 30 of the heat sink 39 and of the supplementary heat sink 15 arranged on the front side 32. The cooling effect of these two heat sinks is enhanced accordingly.

FIG. 4 represents a variant of the cooling arrangement, wherein the latter is configured as a structural unit. The heat sink 13 functions as a carrier for the individual elements, wherein the former is provided on one side with a control module 18, which actuates a converter 14, wherein the latter is attached to the control module 18. The supplementary heat sink 15 is fitted to the other side of the converter 14.

A further possibility is provided, wherein the module, as also represented, is arranged between two ribs 30 of the heat sink 13. In this case, the heat sink 15 is configured with a geometry which essentially corresponds to that of the cooling ribs 30, such that the supplementary heat sink 15 replaces one of said ribs. The supplementary heat sink 15 bifurcates at the base thereof and, between this bifurcation, incorporates a space for the control module 18, the piezo actuator 37 and the fan 38. The fan 38 can therefore operate in an opening, which is not represented, and effects an exchange of air between the adjoining interspaces 40 constituted by the ribs 13 and the supplementary heat sink 15.

The outer edges of the supplementary heat sink 15 constitute mounting surfaces for converters 14 in the form of Peltier elements which, on their respective other side, are connected to the ribs 30 of the heat sink 13, thereby securing the resulting modular unit between the ribs 30. The supplementary heat sink 15 does not contact the heat sink 13 directly at any point, such that the latter can be operated in a different temperature range.

FIG. 5 likewise represents a structural unit. In this case, however, the converter 14 comprises a thermomechanical actuator which, for example, is constituted by a bimetallic strip or formed of a shape memory alloy. This is secured at one end in a clamp 41. The free end thereof constitutes a pivot 42, which is also connected to a fan 38 which rotates about an axis of rotation 43. According to the temperature, the converter 14 undergoes deformation along the double-headed arrow 44, as a result of which, by means of the pivot 42, the fan 38 executes a fanning action.

The pivot 42 is also connected to a storage block 45 for heat, e.g. of copper construction. By the movement of the converter 14, this storage block engages in an alternating manner with the hotter heat sink 13 and the cooler supplementary heat sink 15. This effects the alternating heating and cooling of the storage block which, in turn, alternately heats and cools the converter. Accordingly, this results in the movement of the converter 14 (conversion of thermal energy into mechanical energy).

FIG. 6 represents an option for the configuration of the piezo fan 23 as a structural unit with the heat sink 13. The latter is configured with a comb-like structure, such that the fans 38 respectively project into the interspaces 40 between the ribs 30. As can be seen from FIG. 7, to this end, the fans 38 are angled away from a common base strip 46. This base strip 46 engages with the outer side of the heat sink 13, and is otherwise in contact with piezo actuators 37. Accordingly, upon the actuation of the piezo actuators 37, the fans 38 execute a fanning motion along the double-headed arrow 39.

The piezo actuators 37 are driven by converters 14 in the form of Peltier elements, which are arranged in the lower region of the heat sink 13. The heat sink is of rectangular design, wherein the converters 14 are fitted to the respectively opposing outer sides thereof, and is rotated through an angle of 90° in relation to the two respective outer sides of the piezo fan 23. On the side thereof which is averted from the heat sink 13, the Peltier elements each incorporate a supplementary heat sink 15. The structure of the Peltier elements employed is likewise indicated, and is generally known per se. This structure is comprised of contact blocks of p-doped semiconductors 47 and n-doped semiconductors 48, which are respectively connected by means of contact pieces 49 to form a circuit. The converter 14 is arranged on an electrically insulating layer 50, which provides electrical insulation vis-á-vis the heat sink 13.

What is claimed is:

1. A cooling arrangement for an electronic component, the arrangement comprising:
a heat sink with a contact surface for the electronic component;
a converter for the conversion of thermal energy into useful energy;
a functional element driven by the useful energy; and
an active cooling device for the heat sink or for the electronic component.

2. The cooling arrangement as claimed in claim 1, wherein the converter comprises a thermoelectric generator.

3. The cooling arrangement as claimed in claim 2, wherein the thermoelectric generator and the functional element are connected to an electrical energy store.

4. The cooling arrangement as claimed in claim 1, wherein the cooling device comprises at least one of: a piezo fan, a motor-driven fan, and a Peltier element.

5. The cooling arrangement as claimed in claim 1, wherein the functional element comprises at least one of: a monitoring device, an indicator device, and a data transmission device.

6. The cooling arrangement as claimed in claim 1, wherein the converter is bonded with a supplementary heat sink.

7. The cooling arrangement as claimed in claim 1, wherein a plurality of modules in the cooling arrangement constitute a structural unit.

8. The cooling arrangement as claimed in claim 7, that wherein the converter is bonded to the heat sink.

9. The cooling arrangement as claimed in claim 8, wherein:
the heat sink comprises ribs; and
the converter is arranged between adjoining ribs.

10. The cooling arrangement as claimed in claim 2, further comprising a control module for the functional element; or for the thermoelectric generator; and
wherein the control module consumes energy generated by the thermoelectric generator.

11. An electronic assembly comprising:
an electronic component;
a plurality of heat sinks each with a contact surface for the electronic component;
a converter for the conversion of thermal energy into useful energy;
a functional element driven by the useful energy; and
an active cooling device for the plurality of heat sinks or for the electronic component;
wherein a plurality of heat sinks, in combination with the electronic component, are mounted on a circuit carrier.

12. The electronic assembly as claimed in claim 11, wherein the converter is arranged on a reverse side of the circuit carrier.

13. The electronic assembly as claimed in claim 11, wherein the converter is bonded to the electronic component, or to a thermal conduction path originating from the electronic component.
